(19) United States
(12) Patent Application Publication
(10) Pub. No.: US 2026/0265946 A1
(43) Pub. Date: Sep. 10, 2026

(54) METHOD FOR SIMULTANEOUSLY PRODUCING MULTIPLE SHEETS OF SIC SINGLE CRYSTAL SUBSTRATE

(71) Applicant: NGK Corporation, Nagoya-shi (JP)

(72) Inventors: Yohei OKADA, Nagoya-city (JP); Kiyoshi MATSUSHIMA, Nagoya-city (JP); Jun YOSHIKAWA, Nagoya-city (JP)

(21) Appl. No.: 19/662,291

(22) Filed: Apr. 29, 2026

Related U.S. Application Data
(63) Continuation of application No. PCT/JP2025/009341, filed on Mar. 12, 2025.

(30) Foreign Application Priority Data
Jul. 29, 2024 (JP) 2024-122577

(51) Int. Cl. C30B 17/00; C30B 29/36

(52) U.S. Cl. CPC C30B 17/00; C30B 29/36

(57) ABSTRACT

There is provided a method capable of simultaneously manufacturing multiple SiC single crystal substrates including: preparing multiple containers; placing, in each of the multiple containers, an SiC single crystal serving as a seed crystal and an SiC mixed powder containing SiC powder and a liquid phase sintering aid so as to form an SiC mixed powder layer in which the SiC mixed powder is in contact with the SiC single crystal, wherein the liquid phase sintering aid contains an oxide; arranging the multiple containers in a firing furnace so as to be aligned horizontally and/or vertically; and heating the inside of the firing furnace to form a temperature gradient, and subjecting the multiple containers containing the seed crystal and the SiC mixed powder to heat treatment at an average furnace temperature of 2,240 to 2,560° C., whereby an SiC single crystal is grown on the seed crystal.

### CROSS-REFERENCE TO RELATED APPLICATIONS

This application is a continuation application of PCT/JP2025/009341 filed Mar. 12, 2025, which claims priority to Japanese Patent Application No. 2024-122577 filed Jul. 29, 2024, the entire contents all of which are incorporated herein by reference.

### BACKGROUND OF THE INVENTION

### 1. Field of the Invention

The present disclosure relates to a method for simultaneously manufacturing multiple SiC single crystal substrates.

### 2. Description of the Related Art

SiC (silicon carbide) has been attracting attention as a wide-bandgap material capable of controlling high voltage and high power with low loss. In particular, in recent years, power semiconductor devices using SiC material (SiC power devices) are expected to be used in various applications because they offer advantages such as downsizing, power saving, and higher efficiency compared with devices using Si semiconductors. For example, the adoption of SiC power devices makes it possible to reduce the size and improve the efficiency of converters, inverters, and on-board chargers for electric vehicles (EVs) and plug-in hybrid vehicles (PHEVs).

When manufacturing SiC power devices, a nitrogen-doped, low-resistance SiC wafer is used as a base substrate. Low-resistance SiC wafers can generally be fabricated by the sublimation recrystallization method, but a large thermal gradient arises inside the growth furnace, which is likely to cause thermal strain in the crystal and results in a high crystal defect density. In addition, when defects, especially basal-plane dislocations known as device-killer defects, are present in the SiC wafer, the electrical resistance increases during device operation, which leads to deterioration in device performance.

As methods for reducing defects in wafers, the RAF (Repeated A-Face) method and the solution growth method are known. However, the RAF method has drawbacks such as difficulty in increasing diameter, and high cost, while the solution growth method tends to cause inclusions in the crystal.

As another example of a manufacturing method for reducing defects, Patent Literature 1 (Japanese Patent No. 4069508) discloses a method for manufacturing an SiC single crystal in which micropipes are closed, the method comprising embedding an SiC single crystal in SiC powder and subjecting it to heat treatment. Patent Literature 2 (Japanese Patent No. 7339434) discloses a method for manufacturing an SiC single crystal substrate, the method comprising the steps of placing an SiC single crystal as a seed crystal and an SiC powder layer in contact with each other in a container; and placing the container in an effective working zone of a firing furnace controlled to a temperature range within ±50° C. of a set temperature, performing heat treatment, and thereby growing an SiC single crystal on the seed crystal. In this manufacturing method, heat treatment is carried out under a smaller temperature gradient, and therefore an SiC single crystal substrate with low basal-plane dislocation density and small warpage can be manufactured.

### CITATION LIST

### Patent Literature

Patent Literature 1: Japanese Patent No. 4069508
Patent Literature 2: Japanese Patent No. 7339434

### SUMMARY OF THE INVENTION

As described above, although various methods for reducing defects (dislocations) in SiC single crystal substrates have been studied, further improvement is required. For example, Patent Literature 1 addresses reduction of micropipes; however, since no new SiC single crystal is grown on the SiC single crystal embedded in SiC powder, dislocations other than micropipes cannot be reduced. Patent Literature 2 can reduce basal-plane dislocation density, but it is unclear whether multiple substrates can be grown simultaneously, and no mention is made of the thickness of the resulting SiC single crystal substrate. In this regard, in order to enhance productivity, it is desirable to achieve the crystal growth of many SiC single crystal substrates while maintaining quality.

The present inventors have now found that, by bringing an SiC single crystal serving as a seed crystal into contact with a SiC mixed powder layer containing a liquid phase sintering aid and performing heat treatment in a firing furnace having a predetermined temperature gradient, it is possible to manufacture multiple SiC single crystal substrates with small warpage, low basal-plane dislocation density, and large crystal growth thickness simultaneously.

Accordingly, an object of the present invention is to provide a method capable of simultaneously manufacturing multiple SiC single crystal substrates with small warpage, low basal-plane dislocation density, and large crystal growth thickness.

The present invention provides the following aspects:

### [Aspect 1]

A method for simultaneously manufacturing multiple SiC single crystal substrates, the method comprising the steps of:
preparing a plurality of containers;
placing, in each of the plurality of containers, an SiC single crystal serving as a seed crystal and an SiC mixed powder comprising SiC powder and a liquid phase sintering aid so as to form an SiC mixed powder layer in which the SiC mixed powder is in contact with at least one surface of the SiC single crystal, wherein the liquid phase sintering aid comprises an oxide;
arranging the plurality of containers in a firing furnace so as to be aligned horizontally and/or vertically; and
heating the inside of the firing furnace to form a temperature gradient in which the temperature increases or decreases from an upper part to a lower part of the firing furnace, and subjecting the plurality of containers containing the seed crystal and the SiC mixed powder to heat treatment at an average furnace temperature of 2,240 to 2,560° C., whereby an SiC single crystal is grown on the seed crystal.

### [Aspect 2]

The method according to aspect 1, wherein the oxide comprises a rare earth element.

### [Aspect 3]

The method according to aspect 1 or 2, wherein the content of the oxide is 0.5 to 33.0% by weight relative to the content of the SiC powder.

### [Aspect 4]

The method according to any one of aspects 1 to 3, wherein the average furnace temperature during the heat treatment is 2,370 to 2,515° C.

### [Aspect 5]

The method according to any one of aspects 1 to 4, wherein the temperature gradient is 0.01 to 0.40° C./mm.

### [Aspect 6]

The method according to any one of aspects 1 to 5, wherein the heat treatment is performed while providing a temperature gradient such that the temperature on the side of the container closer to the seed crystal is lower than that on the side of the container closer to the SiC mixed powder layer.

### [Aspect 7]

The method according to any one of aspects 1 to 6, wherein the number of the containers is 2 to 80.

### [Aspect 8]

The method according to any one of aspects 2 to 7, wherein the rare earth element comprises at least one selected from the group consisting of Gd, Sm, La, Nd, Y, and Ce.

### [Aspect 9]

The method according to any one of aspects 1 to 8, wherein a dense body having a relative density of 90% or more is placed on the bottom surface and/or the top surface of the SiC mixed powder layer, excluding the surface in contact with the seed crystal.

### [Aspect 10]

The method according to any one of aspects 1 to 9, wherein a dense body having a relative density of 90% or more is placed on the outer periphery of the SiC mixed powder layer.

### [Aspect 11]

The method according to any one of aspects 1 to 10, wherein a dense body having a relative density of 90% or more is placed on the bottom surface and/or the top surface of the SiC mixed powder layer, excluding the surface in contact with the seed crystal, and a dense body having a relative density of 90% or more is also placed on the outer periphery of the SiC mixed powder layer.

### [Aspect 12]

The method according to any one of aspects 1 to 11, wherein the firing furnace comprises an upper heater at the upper part of the firing furnace and a lower heater at the lower part of the firing furnace, and during the heat treatment, the upper heater and the lower heater are set to different temperatures so as to provide the temperature gradient and the average furnace temperature.

### BRIEF DESCRIPTION OF THE DRAWINGS

FIG. 1 is a schematic cross-sectional view illustrating one embodiment of placement of the SiC mixed powder layer and the seed crystal in a container.

FIG. 2 is a schematic cross-sectional view illustrating another embodiment of placement of the SiC mixed powder layer and the seed crystal in a container.

FIG. 3 is a schematic cross-sectional view illustrating another embodiment of placement of the SiC mixed powder layer and the seed crystal in a container.

FIG. 4 is a schematic cross-sectional view illustrating another embodiment of placement of the SiC mixed powder layer and the seed crystal in a container.

FIG. 5 is a schematic cross-sectional view illustrating one embodiment of placement of the SiC mixed powder layer, the seed crystal, and the dense body in a container.

FIG. 6 is a schematic cross-sectional view illustrating another embodiment of placement of the SiC mixed powder layer, the seed crystal, and the dense body in a container.

FIG. 7 is a schematic cross-sectional view illustrating another embodiment of placement of the SiC mixed powder layer, the seed crystal, and the dense body in a container.

FIG. 8 is a schematic cross-sectional view illustrating another embodiment of placement of the SiC mixed powder layer, the seed crystal, and the dense body in a container.

FIG. 9 is a schematic cross-sectional view illustrating another embodiment of placement of the SiC mixed powder layer, the seed crystal, and the dense body in a container.

FIG. 10 is a schematic cross-sectional view illustrating the configuration of a firing furnace used for crystal growth.

FIG. 11 is a top view of an SiC single crystal substrate 20 for illustrating a method for measuring the warpage of the SiC single crystal substrate 20.

FIG. 12 is a schematic cross-sectional view of an SiC single crystal substrate 20 for illustrating a method for measuring the warpage of the SiC single crystal substrate 20.

FIG. 13 is a schematic cross-sectional view of an SiC single crystal substrate 20 for illustrating a method for measuring the warpage of the SiC single crystal substrate 20.

### DETAILED DESCRIPTION OF THE INVENTION

### Method for Manufacturing SiC Single Crystal Substrates

The present invention relates to a method for simultaneously manufacturing multiple SiC single crystal substrates. In this method of manufacturing, first, a plurality of containers is prepared. Then, in each of the plurality of containers, an SiC single crystal serving as a seed crystal and an SiC mixed powder comprising SiC powder and a liquid phase sintering aid are placed so as to form an SiC mixed powder layer in which the SiC mixed powder is in contact with at least one surface of the SiC single crystal. The liquid phase sintering aid comprises an oxide. Next, the plurality of containers is arranged in a firing furnace so as to be aligned horizontally and/or vertically. Finally, the inside of the firing furnace is heated to form a temperature gradient in which the temperature increases or decreases from an upper part to a lower part of the firing furnace, and the plurality of containers containing the seed crystal and the SiC mixed powder is subjected to heat treatment at an average furnace temperature of 2,240 to 2,560° C. As a result, an SiC single crystal grows on the seed crystal. In this manner, by heat-treating the SiC single crystal serving as the seed crystal and the SiC mixed powder layer containing the liquid-phase sintering aid while they are in contact with each other inside a firing furnace having a predetermined temperature gradient, multiple SiC single crystal substrates with small warpage, low basal-plane dislocation density, and large crystal growth thickness can be simultaneously manufactured.

As described above, although various methods for reducing defects (dislocations) in SiC single crystal substrates have been studied, further improvement is required. For example, Patent Literature 1 addresses reduction of micropipes; however, since no new SiC single crystal is grown on the SiC single crystal embedded in SiC powder, dislocations other than micropipes cannot be reduced. Patent Literature 2 can reduce basal-plane dislocation density, but it is unclear whether multiple substrates can be grown simultaneously, and no mention is made of the thickness of the resulting SiC single crystal substrate. In this regard, in order to enhance productivity, it is desirable to achieve the crystal growth of many SiC single crystal substrates while maintaining quality. According to the present invention, such issues are advantageously solved. Specifically, multiple SiC single crystal substrates with a crystal growth thickness of 50 μm or more, a warpage of 40 μm or less, and a basal-plane dislocation density of 100 cm² or less can be simultaneously manufactured.

### (1) Preparation of Containers

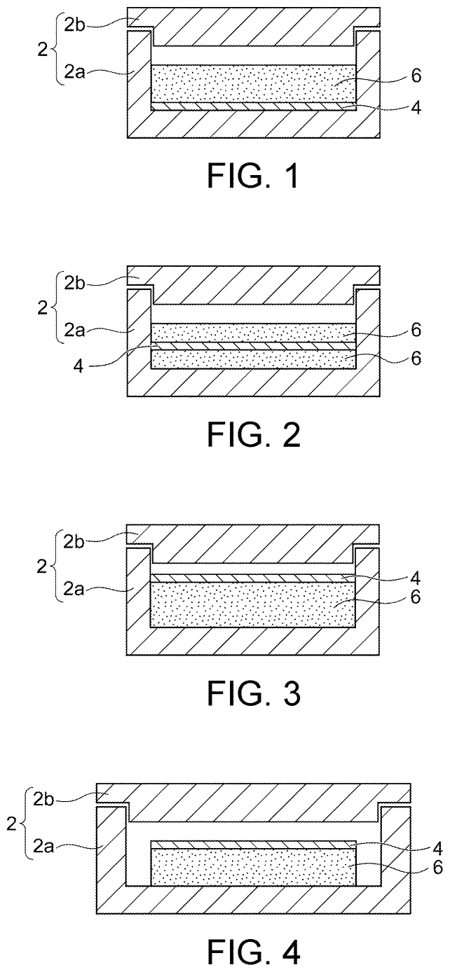

Since the present invention is a method for simultaneously manufacturing multiple SiC single crystal substrates, a plurality of containers for accommodating the seed crystal and the SiC mixed powder is first prepared. The material of the container is not particularly limited as long as it does not sublime or melt at the furnace temperature during heat treatment, but graphite or SiC is preferable. In addition, the inner wall or outer wall of the container may be coated. Examples of coating materials include SiC, TiC, TaC, NbC, and WC. The shape of the container is not particularly limited, but as shown in FIG. 1, it is preferable that the container comprises a container body 2a having an open top and an internal space capable of accommodating the seed crystal 4 and the SiC mixed powder layer 6, and a container lid 2b fitted to the open top of the container body 2a.

### (2) Placement of SiC Mixed Powder and Seed Crystal

Next, in each of the plurality of containers 2, an SiC single crystal serving as the seed crystal 4 and an SiC mixed powder comprising SiC powder and a liquid phase sintering aid are placed so as to form an SiC mixed powder layer 6 in which the SiC mixed powder is in contact with at least one surface of the SiC single crystal. The seed crystal 4 is typically composed of an SiC single crystal and has a crystal growth surface. The polytype, off-angle, and polarity of the SiC single crystal, as well as the type and concentration of dopants that may be contained in the SiC single crystal, are not particularly limited, but polytypes 4H, 6H, and 3C are preferable. An SiC single crystal formed on an Si substrate may also be used as the seed crystal 4. The crystal growth surface of the SiC single crystal serving as the seed crystal 4 may be the Si-face or the C-face, or both of the Si-face and the C-face. The diameter of the seed crystal 4 is not particularly limited and may be, for example, 100 mm (4 in.), 150 mm (6 in.), or 200 mm (8 in.).

The SiC mixed powder layer 6 typically refers to an SiC mixed powder placed as a layer inside the container 2. The SiC mixed powder is preferably prepared by uniformly mixing SiC powder and a liquid phase sintering aid. The mixing method is not particularly limited as long as the SiC powder and the liquid phase sintering aid can be uniformly mixed, and may be, for example, a ball mill mixing or mixer mixing. A dispersant or the like may be added during mixing of the SiC powder and the liquid phase sintering aid to suppress agglomeration.

The SiC powder may be either a-SiC or p-SiC, as long as it serves as the SiC source during crystal growth. The particle size and purity of the SiC powder are not particularly limited, and any commercially available powder may be used. However, to produce a high-purity SiC single crystal substrate, it is preferable that the SiC powder also be of high purity.

The liquid-phase sintering aid is an additive that generates a liquid phase during the heat treatment described later (particularly in the vicinity of the crystal growth temperature, e.g., at the average furnace temperature) and serves to dissolve SiC particles (SiC powder) by melting to form the liquid phase. The liquid phase sintering aid comprises an oxide. The oxide contained in the liquid-phase sintering aid preferably contains a metal element (that is, is in the form of a metal oxide), and more preferably contains a rare earth element. Examples of preferred rare earth elements include Gd, Sm, La, Nd, Y, and Ce, and combinations thereof, and Gd, Sm, La, and combinations thereof are more preferred. Examples of preferred metal elements other than rare earth elements include Al and Nb. The oxide contained in the liquid phase sintering aid may contain an element other than a metal element, and a preferred example of such an element is Si.

The content of the oxide contained in the liquid phase sintering aid is preferably 0.5 to 37.0% by weight, more preferably 0.5 to 33.0% by weight, further preferably 1.0 to 25.0% by weight, particularly preferably 2.0 to 17.0% by weight, and most preferably 4.0 to 10.0% by weight based on the content of the SiC powder (taken as 100% by weight).

As shown in FIG. 1 to FIG. 4, the SiC mixed powder is placed so as to form an SiC mixed powder layer 6 in which the SiC mixed powder is in contact with at least one surface of the SiC single crystal serving as the seed crystal 4. That is, as long as the seed crystal 4 and the SiC mixed powder layer 6 are in contact with each other, their placement is not particularly limited. For example, as shown in FIG. 1, the seed crystal 4 may be placed on the inner bottom surface of the container 2, and the SiC mixed powder layer 6 may be placed on top of it. As shown in FIG. 2, the seed crystal 4 may be embedded in the SiC mixed powder layer 6 in the container 2. Alternatively, as shown in FIG. 3, the seed crystal 4 may be placed on the top surface of the SiC mixed powder layer 6 that is disposed on the inner bottom surface of the container 2. In addition, as long as the seed crystal 4 and the SiC mixed powder layer 6 are in contact, multiple seed crystals 4 may be placed in a single container 2. Furthermore, as shown in FIG. 4, as long as the seed crystal 4 and the SiC mixed powder layer 6 are in contact, a lateral space may be provided so that the side surfaces (outer periphery) of the seed crystal 4 and the SiC mixed powder layer 6 do not come into contact with the inner wall of the container 2. The method for filling the SiC mixed powder into the container 2 is not particularly limited and may be carried out by known techniques such as press filling or vibration filling.

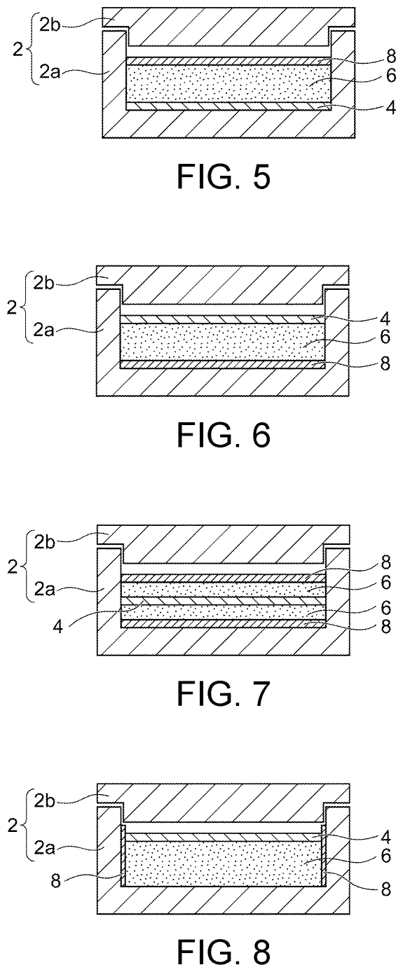

As shown in FIG. 5 to FIG. 7, a dense body 8 may be placed on the bottom surface and/or the top surface of the SiC mixed powder layer 6 (excluding the surface in contact with the seed crystal 4). By placing a dense body 8 in the above-described manner, impurities from the inner bottom surface of the container 2 and/or the container lid 2b can be prevented from entering, thereby enabling the growth of a higher-purity SiC single crystal. For example, when the seed crystal 4 is not placed on the top surface of the SiC mixed powder layer 6, a dense body 8 may be placed on the top surface of the SiC mixed powder layer 6 as shown in FIG. 5. When the seed crystal 4 is not placed on the inner bottom surface of the container 2, a dense body 8 may be placed between the SiC mixed powder layer 6 and the inner bottom surface of the container 2 as shown in FIG. 6. When the seed crystal 4 is embedded in the SiC mixed powder layer 6, a dense body 8 may be placed on the top surface of the SiC mixed powder layer 6 and/or between the SiC mixed powder layer 6 and the inner bottom surface of the container 2, as shown in FIG. 7.

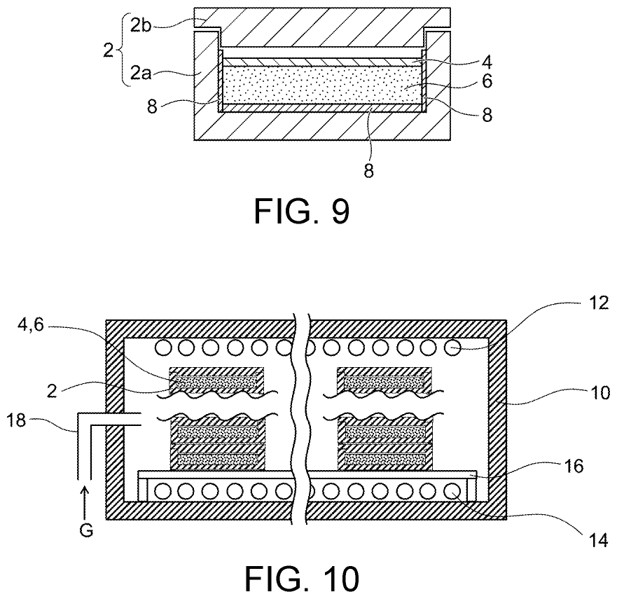

As shown in FIG. 8 and FIG. 9, a dense body 8 may be placed at the outer periphery of the SiC mixed powder layer 6. By placing a dense body 8 in the above-described manner, impurities from the side surfaces of the container 2 can be prevented from entering, thereby enabling the growth of a higher-purity SiC single crystal. For example, as shown in FIG. 8, a dense body 8 may be placed between the outer peripheral portion of the SiC mixed powder layer 6 and the inner wall of the container 2. In this case, it is preferable that at least the outer peripheral portion of the SiC mixed powder layer 6 is in contact with the dense body 8. In particular, as shown in FIG. 9, it is preferable that a dense body 8 be placed on the bottom surface and/or the top surface of the SiC mixed powder layer 6 (excluding the surface contacting the seed crystal 4), as well as at the outer periphery of the SiC mixed powder layer 6.

The dense body 8 is preferably a solid having a relative density of 90% or more, more preferably 95% or more, and further preferably 99% or more. The higher the relative density, the more effectively the intrusion of impurities can be prevented. The relative density can be determined, for example, by dividing the measured bulk density of the dense body by its theoretical density using the Archimedes method, and multiplying the resulting value by 100. The dense body 8 is not particularly limited as long as it does not sublime or melt at the furnace temperature during heat treatment and does not react with SiC. Examples of materials for such a dense body 8 include carbides such as TiC, TaC, NbC, and WC, and polycrystalline nitrides such as Si₃N₄ and TiN. The shape of the dense body 8 is not particularly limited, but a layered shape is preferable.

### (3) Arrangement of Multiple Containers in Firing Furnace

As described above, multiple containers 2 in which the SiC mixed powder layer 6, the seed crystal 4, and, optionally, the dense body 8 are disposed are placed in the firing furnace 10 so as to be aligned horizontally and/or vertically. From the viewpoint of productivity improvement, it is desirable to place a larger number of containers 2 in the firing furnace 10. Therefore, the number of containers 2 is preferably 2 or more, more preferably 2 to 80, further preferably 15 to 80, and particularly preferably 50 to 80, and may be, for example, 2 to 15 or 15 to 50. More specifically, when multiple containers 2 are arranged vertically (e.g., stacked), the number of containers 2 arranged vertically is preferably 2 to 30, more preferably 5 to 30, further preferably 10 to 30, and particularly preferably 20 to 30, and may be, for example, 2 to 5, 5 to 10, or 10 to 20. When multiple containers 2 are arranged horizontally, either individually and/or as sets of containers 2 arranged vertically, the number of containers 2 and/or sets arranged horizontally is preferably 2 to 10, more preferably 4 to 10, further preferably 6 to 10, and particularly preferably 8 to 10, and may be, for example, 2 to 4, 4 to 6, or 6 to 8. As shown in FIG. 10, the firing furnace 10 preferably comprises an upper heater 12 disposed at the upper part of the firing furnace 10, a lower heater 14 disposed at the lower part of the firing furnace 10, a support base 16 on which multiple containers 2 are placed, and a gas pipe 18 for supplying gas G into the firing furnace 10. With this configuration, a temperature gradient in which the temperature increases or decreases from the upper part to the lower part of the firing furnace 10 can be effectively formed during the subsequent heat treatment step.

### (4) Heat Treatment

After arranging multiple containers 2 in the firing furnace 10, the inside of the firing furnace 10 is heated so as to form a temperature gradient in which the temperature increases or decreases from the upper part to the lower part of the firing furnace 10. The containers 2 containing the seed crystal 4 and the SiC mixed powder layer 6 are then subjected to heat treatment at an average furnace temperature of 2,240 to 2,560° C., thereby growing an SiC single crystal on the seed crystal 4. At this time, as shown in FIG. 10, it is preferable that the firing furnace 10 include an upper heater 12 disposed at the upper part of the firing furnace 10 and a lower heater 14 disposed at the lower part of the firing furnace 10, and that, during heat treatment, the upper heater 12 and the lower heater 14 be set to different temperatures so as to provide the above temperature gradient and the above average furnace temperature. When heating is performed so as to form a temperature gradient in which the temperature increases from the upper part to the lower part of the firing furnace 10, the lower heater 14 may simply be set to a higher temperature than the upper heater 12. Conversely, when heating is performed so as to form a temperature gradient in which the temperature decreases from the upper part to the lower part of the firing furnace 10, the lower heater 14 may simply be set to a lower temperature than the upper heater 12.

It is preferable that the containers 2 be placed in the effective working zone of the firing furnace 10. Here, the “effective working zone” refers to “the charging region in a heating equipment capable of holding metal products within a permissible range of temperature according to the purposes of the heat treatment,” as defined in JIS B 6905:1995. The temperature of the effective working zone of the firing furnace 10 can be controlled by adjusting the output of the upper heater 12 and the lower heater 14 provided in the firing furnace 10. This allows the upper and lower temperatures of the heating region in the firing furnace 10 to be adjusted, thereby forming a unidirectional temperature gradient in the firing furnace 10.

The temperature gradient is preferably 0.01 to 0.40° C./mm, more preferably 0.05 to 0.30° C./mm, further preferably 0.08 to 0.14° C./mm. It is also preferable to perform the heat treatment while providing a temperature gradient such that the temperature on the side of the container 2 closer to the seed crystal 4 is lower than that on the side of the container 2 closer to the SiC mixed powder layer 6. For example, when heating is performed so as to form a temperature gradient in which the temperature increases from the upper part to the lower part of the firing furnace 10, the seed crystal 4 may be placed on the SiC mixed powder layer 6 in the container 2. Conversely, when heating is performed so as to form a temperature gradient in which the temperature decreases from the upper part to the lower part of the firing furnace 10, the SiC mixed powder layer 6 may be placed on the seed crystal 4 in the container 2.

The average furnace temperature during the heat treatment is 2,240 to 2,560° C., preferably 2,370 to 2,515° C., more preferably 2,390 to 2,480° C., and even more preferably 2,410 to 2,450° C. The average furnace temperature may be determined as the average of the highest temperature and the lowest temperature in the effective working zone of the firing furnace 10. Typically, the temperature in the vicinity of the lowest part of the effective working zone of the firing furnace 10 and the temperature in the vicinity of the highest part are measured, and the average of these temperatures may be adopted as the average furnace temperature. The holding time at the above average furnace temperature is not particularly limited, and a longer holding time allows the SiC single crystal to grow to a greater thickness. Accordingly, the holding time may be set in accordance with the desired thickness. The heat treatment may be carried out under atmospheric pressure or under an applied pressure, such as in a hot press.

The firing furnace 10 used for the heat treatment is not particularly limited as long as crystal growth of SiC occurs on the seed crystal 4, and may be a known firing furnace such as a resistance furnace, an arc furnace, or an induction furnace. The atmosphere in the firing furnace 10 during firing is preferably vacuum, nitrogen, an inert gas, or a mixed atmosphere of nitrogen and an inert gas. The material and resistivity of the heaters 12 and 14 are not particularly limited, but graphite is preferred.

### (5) Polishing

After the SiC single crystal is grown on the seed crystal 4 as described above, it is preferable to polish the surface of the SiC single crystal. For example, after polishing with diamond abrasive grains, chemical mechanical polishing (CMP) finishing is performed to obtain the desired SiC single crystal substrate.

### EXAMPLES

The present invention will be described in more detail with reference to the following Examples. However, the present invention is not limited to these Examples.

### Example 1

### (1) Preparation of SiC Mixed Powder

A commercially available p-SiC powder (volume-based D50 particle size: 65.0 μm) and an oxide (Gd₂O₃) serving as a liquid phase sintering aid (volume-based D50 particle size: 5.0 μm) were weighed such that the content of the oxide was 8.1% by weight relative to the content of the SiC powder. Then, the powders were charged into a polypropylene container together with pebbles and water. The polypropylene container was mounted on a pot stand and then rotated at a rate of 50 rpm to mix the raw materials. The slurry obtained by mixing the raw materials was dried in a drying machine, and recovered to obtain the SiC mixed powder.

### (2) Placement of SiC Mixed Powder and SiC Single Crystal

The SiC mixed powder obtained in (1) above was filled into a graphite container and tapped to level the SiC mixed powder so that its outermost surface appeared flat. A commercially available SiC single crystal substrate (4H-SiC, diameter 150 mm (6 in.), off-angle 4°, thickness 0.35 mm), which served as the seed crystal, was placed on the SiC mixed powder such that only the Si face of the seed crystal was in contact with the powder. The graphite container was closed with a graphite lid to form a single graphite crucible. A plurality of such graphite crucibles (four in total in this example) was prepared.

### (3) Arrangement of Multiple Graphite Crucibles in Resistance Furnace

The graphite crucibles prepared in (2) above were arranged in the effective working zone of a firing furnace (resistance furnace) by placing two crucibles vertically with a 5-mm-thick graphite spacer interposed therebetween, and arranging two such sets horizontally. Thus, a total of four graphite crucibles were arranged in the furnace.

### (4) Heat Treatment

By adjusting the output of the heater, a temperature gradient of 0.11° C./mm was formed such that the temperature in the firing furnace increased from the upper part toward the lower part. Under an argon atmosphere, all the graphite crucibles were heat treated at an average furnace temperature of 2,430° C. for 20 hours. As a result, SiC single crystal substrates in which SiC single crystal was grown on the seed crystal were obtained in all the graphite crucibles.

### (5) Measurement of Crystal Growth Thickness of SiC Single Crystal Substrate

The thickness of the SiC single crystal substrate obtained in (4) above was measured at 25 randomly selected points using a micrometer, and the arithmetic mean value was calculated. Similarly, the thickness of the seed crystal at the stage of (2) above was also determined. The crystal growth thickness (μm) was calculated by subtracting the arithmetic mean value of the thickness of the seed crystal from the arithmetic mean value of the thickness of the SiC single crystal substrate. It was confirmed that the crystal growth thickness of each of the four SiC single crystal substrates was 100 μm or more.

Among all the SiC single crystal substrates whose crystal growth thickness was determined by the above method, the SiC single crystal substrate having the smallest crystal growth thickness was evaluated and rated according to the following evaluation criteria. The results were as shown in Table 3.

### <Evaluation Criteria>

Rating A: The crystal growth thickness of the SiC single crystal substrate having the smallest crystal growth thickness is 100 μm or more.
Rating B: The crystal growth thickness of the SiC single crystal substrate having the smallest crystal growth thickness is 50 μm or more and less than 100 μm.
Rating C: The crystal growth thickness of the SiC single crystal substrate having the smallest crystal growth thickness is less than 50 μm.

### (6) Polishing

The surfaces (Si face and C face) of the resulting SiC single crystal were polished using diamond abrasive grains and then finished by chemical mechanical polishing (CMP).

### (7) Measurement of Warpage of SiC Single Crystal Substrate

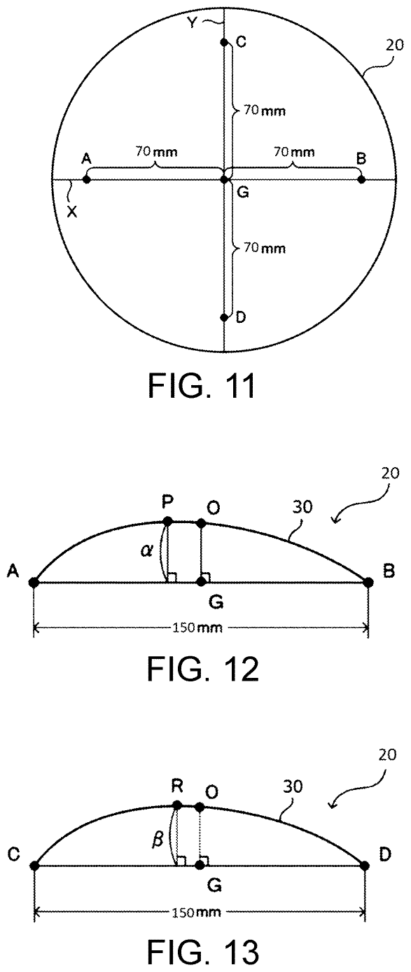

The warpage of the polished surfaces of all the SiC single crystal substrates obtained in (6) above was measured using a high-precision laser measuring instrument (Model LT-9010M, manufactured by Keyence Corporation). As shown in FIG. 11, in the plan-view shape of the surface (SiC single crystal 30) of the SiC single crystal substrate 20, two orthogonal straight lines X and Y are drawn through the centroid G of the plan-view shape. Two points A and B, each located 70 mm from point G on straight line X, and two points C and D, each located 70 mm from point G on straight line Y, were defined. Next, as shown in FIG. 12, among the line segments drawn from any point on the curve AB between points A and B on the surface (SiC single crystal 30) of the SiC single crystal substrate 20 perpendicularly to the line segment AB, the point P on the curve AB that gives the longest perpendicular distance to the line segment AB was determined (for example, points on the curve AB may include points P and 0, but the line segment drawn from point P is the longest among the line segments drawn perpendicularly to the line segment AB from each point). The distance between the line segment AB and point P was taken as warpage α. Similarly, as shown in FIG. 13, among the line segments drawn from any point on the curve CD between points C and D on the surface (SiC single crystal 30) of the SiC single crystal substrate 20 perpendicularly to the line segment CD, the point R on the curve CD that gives the longest perpendicular distance to the line segment CD was determined (for example, points on the curve CD may include points R and 0, but the line segment drawn from point R is the longest among the line segments drawn perpendicularly to the line segment CD from each point). The distance between the line segment CD and point R was taken as warpage β. The average of these warpages α and β was taken as the warpage of the SiC single crystal substrate.

Among all the SiC single crystal substrates whose warpage was determined by the above method, the SiC single crystal substrate having the largest warpage was evaluated and rated according to the following evaluation criteria. The results were as shown in Table 3.

### <Evaluation Criteria>

Rating A: The warpage of the SiC single crystal substrate with the largest warpage is 30 μm or less.
Rating B: The warpage of the SiC single crystal substrate with the largest warpage exceeds 30 μm and is 40 μm or less.
Rating C: The warpage of the SiC single crystal substrate with the largest warpage exceeds 40 μm.

### (8) Measurement of Basal-Plane Dislocation Density of SiC Single Crystal Substrate

All the SiC single crystal substrates obtained in (6) above were placed in a nickel crucible together with KOH crystal. The SiC single crystal substrates in the crucible were subjected to etching in an electric furnace at 500° C. for 10 minutes. The etched samples (SiC single crystal substrates) were washed, and their surface was observed under an optical microscope to identify the types of defects based on the shapes of the pits. Among these, the number of basal-plane dislocations was measured, and the basal-plane dislocation density (cm⁻²) was calculated by dividing the number of basal-plane dislocations by the area (cm²) of the observation region. Specifically, for any location on the sample surface, 100 fields of view measuring 2.8 mm in the vertical direction and 3.6 mm in the horizontal direction at 20× magnification were captured, and the total number of basal-plane dislocations was counted. The basal-plane dislocation density was calculated by dividing the total number by the total area of the 100 fields of view, which was 10.1 cm².

Among all the SiC single crystal substrates whose basal-plane dislocation density was determined by the above method, the SiC single crystal substrate having the highest basal-plane dislocation density was evaluated and rated according to the following evaluation criteria. The results were as shown in Table 3.

### <Evaluation Criteria>

Rating A: The basal-plane dislocation density of the SiC single crystal substrate having the highest basal-plane dislocation density is 80 cm⁻² or less.
Rating B: The basal-plane dislocation density of the SiC single crystal substrate having the highest basal-plane dislocation density exceeds 80 cm⁻² and is 100 cm⁻² or less.
Rating C: The basal-plane dislocation density of the SiC single crystal substrate having the highest basal-plane dislocation density exceeds 100 cm⁻².

### Example 2

A SiC single crystal substrate was prepared and evaluated in the same manner as in Example 1 except that: (i) the content of the oxide was set to 16.2% by weight relative to the content of the SiC powder in (1) above; (ii) a TaC polycrystalline dense body (relative density 90% or more) was placed at the bottom and outer periphery in the graphite container in (2) above; (iii) 3 graphite crucibles were arranged horizontally and 5 graphite crucibles were arranged vertically in the firing furnace in (3) above; and (iv) a temperature gradient of 0.17° C./mm was formed such that the temperature increased from the upper part to the lower part of the firing furnace, and heating was conducted at an average furnace temperature of 2,445° C. in (4) above. The evaluation results for the crystal growth thickness, warpage, and basal-plane dislocation density of the resulting substrate were as shown in Table 3.

### Example 3

A SiC single crystal substrate was prepared and evaluated in the same manner as in Example 1 except that: (i) the content of the oxide was set to 32.4% by weight relative to the content of the SiC powder in (1) above; (ii) a TaC polycrystalline dense body (relative density 90% or more) was placed at the outer periphery in the graphite container in (2) above; (iii) 3 graphite crucibles were arranged horizontally and 25 graphite crucibles were arranged vertically in the firing furnace in (3) above; and (iv) a temperature gradient of 0.06° C./mm was formed such that the temperature increased from the upper part to the lower part of the firing furnace, and heating was conducted at an average furnace temperature of 2,490° C. in (4) above. The evaluation results for the crystal growth thickness, warpage, and basal-plane dislocation density of the resulting substrate were as shown in Table 3.

### Example 4

A SiC single crystal substrate was prepared and evaluated in the same manner as in Example 1 except that: (i) the content of the oxide was set to 4.1% by weight relative to the content of the SiC powder in (1) above; (ii) 10 graphite crucibles were arranged horizontally and 5 graphite crucibles were arranged vertically in the firing furnace in (3) above; and (iii) a temperature gradient of 0.28° C./mm was formed such that the temperature increased from the upper part to the lower part of the firing furnace, and heating was conducted at an average furnace temperature of 2,450° C. in (4) above. The evaluation results for the crystal growth thickness, warpage, and basal-plane dislocation density of the resulting substrate were as shown in Table 3.

### Example 5

A SiC single crystal substrate was prepared and evaluated in the same manner as in Example 1 except that: (i) the content of the oxide was set to 2.0% by weight relative to the content of the SiC powder in (1) above; (ii) a TaC polycrystalline dense body (relative density 90% or more) was placed at the bottom of the graphite container in (2) above; (iii) 2 graphite crucibles were arranged horizontally and 30 graphite crucibles were arranged vertically in the firing furnace in (3) above; and (iv) a temperature gradient of 0.01° C./mm was formed such that the temperature increased from the upper part to the lower part of the firing furnace, and heating was conducted at an average furnace temperature of 2,508° C. in (4) above. The evaluation results for the crystal growth thickness, warpage, and basal-plane dislocation density of the resulting substrate were as shown in Table 3.

### Example 6

A SiC single crystal substrate was prepared and evaluated in the same manner as in Example 1 except that: (i) the content of the oxide was set to 1.0% by weight relative to the content of the SiC powder in (1) above; (ii) a TaC polycrystalline dense body (relative density 90% or more) was placed at the bottom of the graphite container in (2) above; (iii) 7 graphite crucibles were arranged horizontally and 10 graphite crucibles were arranged vertically in the firing furnace in (3) above; and (iv) a temperature gradient of 0.12° C./mm was formed such that the temperature increased from the upper part to the lower part of the firing furnace, and heating was conducted at an average furnace temperature of 2,445° C. in (4) above. The evaluation results for the crystal growth thickness, warpage, and basal-plane dislocation density of the resulting substrate were as shown in Table 3.

### Example 7

A SiC single crystal substrate was prepared and evaluated in the same manner as in Example 1 except that: (i) the content of the oxide was set to 0.8% by weight relative to the content of the SiC powder in (1) above; (ii) a TaC polycrystalline dense body (relative density 90% or more) was placed at the bottom of the graphite container in (2) above; (iii) 1 graphite crucible was arranged horizontally and 2 graphite crucibles were arranged vertically in the firing furnace in (3) above; and (iv) a temperature gradient of 0.14° C./mm was formed such that the temperature increased from the upper part to the lower part of the firing furnace, and heating was conducted at an average furnace temperature of 2,375° C. in (4) above. The evaluation results for the crystal growth thickness, warpage, and basal-plane dislocation density of the resulting substrate were as shown in Table 3.

### Example 8

A SiC single crystal substrate was prepared and evaluated in the same manner as in Example 1 except that: (i) the content of the oxide was set to 24.3% by weight relative to the content of the SiC powder in (1) above; (ii) a TaC polycrystalline dense body (relative density 90% or more) was placed at the bottom and outer periphery in the graphite container in (2) above; (iii) 2 graphite crucibles were arranged horizontally and 1 graphite crucible was arranged vertically in the firing furnace in (3) above; and (iv) a temperature gradient of 0.21° C./mm was formed such that the temperature increased from the upper part to the lower part of the firing furnace, and heating was conducted at an average furnace temperature of 2,463° C. in (4) above. The evaluation results for the crystal growth thickness, warpage, and basal-plane dislocation density of the resulting substrate were as shown in Table 3.

### Example 9

A SiC single crystal substrate was prepared and evaluated in the same manner as in Example 1 except that: (i) in (2) above, a commercially available SiC single crystal substrate serving as the seed crystal was placed at the bottom of the graphite container with its Si face facing upward, and SiC mixed powder was then loaded on top of it; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 10

A SiC single crystal substrate was prepared and evaluated in the same manner as in Example 2 except that: (i) in (2) above, a commercially available SiC single crystal substrate serving as the seed crystal was placed at the bottom of the graphite container with its Si face facing upward, a TaC polycrystalline dense body (relative density 90% or more) was placed at the outer periphery in the graphite container, SiC mixed powder was then loaded on top of it, and a TaC polycrystalline dense body (relative density 90% or more) was also placed on the top surface of the powder layer; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 11

A SiC single crystal substrate was prepared and evaluated in the same manner as in Example 3 except that: (i) in (2) above, a commercially available SiC single crystal substrate serving as the seed crystal was placed at the bottom of the graphite container with its Si face facing upward and SiC mixed powder was then loaded on top of it; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 12

A SiC single crystal substrate was prepared and evaluated in the same manner as in Example 4 except that: (i) in (2) above, a commercially available SiC single crystal substrate serving as the seed crystal was placed at the bottom of the graphite container with its Si face facing upward and SiC mixed powder was then loaded on top of it; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 13

A SiC single crystal substrate was prepared and evaluated in the same manner as in Example 5 except that: (i) in (2) above, a commercially available SiC single crystal substrate serving as the seed crystal was placed at the bottom of the graphite container with its Si face facing upward, SiC mixed powder was then loaded on top of it, and a TaC polycrystalline dense body (relative density 90% or more) was also placed on the top surface of the powder layer; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 14

A SiC single crystal substrate was prepared and evaluated in the same manner as in Example 6 except that: (i) in (2) above, a commercially available SiC single crystal substrate serving as the seed crystal was placed at the bottom of the graphite container with its Si face facing upward, SiC mixed powder was then loaded on top of it, and a TaC polycrystalline dense body (relative density 90% or more) was also placed on the top surface of the powder layer; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 15

A SiC single crystal substrate was prepared and evaluated in the same manner as in Example 7 except that: (i) in (2) above, a commercially available SiC single crystal substrate serving as the seed crystal was placed at the bottom of the graphite container with its Si face facing upward, SiC mixed powder was then loaded on top of it, and a TaC polycrystalline dense body (relative density 90% or more) was also placed on the top surface of the powder layer; and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 16

A SiC single crystal substrate was prepared and evaluated in the same manner as in Example 8 except that: (i) in (2) above, a commercially available SiC single crystal substrate serving as the seed crystal was placed at the bottom of the graphite container with its Si face facing upward, a TaC polycrystalline dense body (relative density 90% or more) was placed at the outer periphery in the graphite container, SiC mixed powder was then loaded on top of it, and a TaC polycrystalline dense body (relative density 90% or more) was also placed on the top surface of the powder layer, and (ii) heating was conducted to form a temperature gradient such that the temperature decreased from the upper part to the lower part in the firing furnace in (4) above. The results of evaluation of the crystal growth thickness, warpage, and basal-plane dislocation density of the resulting substrate were as shown in Table 3.

### Example 17

A SiC single crystal substrate was prepared and evaluated in the same manner as in Example 1 except that Sm₂O₃ was used as the oxide serving as the liquid phase sintering aid in (1) above. The results of evaluation of the crystal growth thickness, warpage, and basal-plane dislocation density of the resulting substrate were as shown in Table 3.

### Example 18

A SiC single crystal substrate was prepared and evaluated in the same manner as in Example 1 except that La₂O₃ was used as the oxide serving as the liquid phase sintering aid in (1) above. The results of evaluation of the crystal growth thickness, warpage, and basal-plane dislocation density of the resulting substrate were as shown in Table 3.

### Example 19

A SiC single crystal substrate was prepared and evaluated in the same manner as in Example 1 except that Nd₂O₃ was used as the oxide serving as the liquid phase sintering aid in (1) above. The results of evaluation of the crystal growth thickness, warpage, and basal-plane dislocation density of the resulting substrate were as shown in Table 3.

### Example 20

A SiC single crystal substrate was prepared and evaluated in the same manner as in Example 1 except that: (i) Y₂O₃ was used as the oxide serving as the liquid phase sintering aid in (1) above; and (ii) a TaC polycrystalline dense body (relative density 90% or more) was placed at the bottom of the graphite container in (2) above. The results of evaluation of the crystal growth thickness, warpage, and basal-plane dislocation density of the resulting substrate were as shown in Table 3.

### Example 21

A SiC single crystal substrate was prepared and evaluated in the same manner as in Example 1 except that: (i) CeO₂ was used as the oxide serving as the liquid phase sintering aid in (1) above; and (ii) a TaC polycrystalline dense body (relative density 90% or more) was placed at the bottom of the graphite container in (2) above. The results of evaluation of the crystal growth thickness, warpage, and basal-plane dislocation density of the resulting substrate were as shown in Table 3.

### Example 22

A SiC single crystal substrate was prepared and evaluated in the same manner as in Example 1 except that: in (2) above, SiC mixed powder was filled to approximately half the height of the graphite container and leveled, a commercially available SiC single crystal substrate serving as the seed crystal was placed on the powder, and the seed crystal was embedded by loading SiC mixed powder on the substrate. The results of evaluation of the crystal growth thickness, warpage, and basal-plane dislocation density of the resulting substrate were as shown in Table 3.

### Example 23

A SiC single crystal substrate was prepared and evaluated in the same manner as in Example 22 except that: (i) Sm₂O₃ was used as the oxide serving as the liquid phase sintering aid in (1) above; and (ii) a TaC polycrystalline dense body (relative density 90% or more) was placed at the bottom of the graphite container and on the top surface of the powder layer in (2) above. The results of evaluation of the crystal growth thickness, warpage, and basal-plane dislocation density of the resulting substrate were as shown in Table 3.

### Example 24

A SiC single crystal substrate was prepared and evaluated in the same manner as in Example 4 except that Al₂O₃ was used as the oxide serving as the liquid phase sintering aid in (1) above. The results of evaluation of the crystal growth thickness, warpage, and basal-plane dislocation density of the resulting substrate were as shown in Table 3.

### Example 25

A SiC single crystal substrate was prepared and evaluated in the same manner as in Example 7 except that: (i) Al₂O₃ was used as the oxide serving as the liquid phase sintering aid in (1) above; and (ii) a TaC polycrystalline dense body (relative density 90% or more) was also placed at the outer periphery in the graphite container in (2) above. The results of evaluation of the crystal growth thickness, warpage, and basal-plane dislocation density of the resulting substrate were as shown in Table 3.

### Example 26

A SiC single crystal substrate was prepared and evaluated in the same manner as in Example 5 except that Al₂O₃ was used as the oxide serving as the liquid phase sintering aid in (1) above. The results of evaluation of the crystal growth thickness, warpage, and basal-plane dislocation density of the resulting substrate were as shown in Table 3.

### Example 27

A SiC single crystal substrate was prepared and evaluated in the same manner as in Example 4 except that Nb₂O₅ was used as the oxide serving as the liquid phase sintering aid in (1) above. The results of evaluation of the crystal growth thickness, warpage, and basal-plane dislocation density of the resulting substrate were as shown in Table 3.

### Example 28

A SiC single crystal substrate was prepared and evaluated in the same manner as in Example 7 except that: (i) Nb₂O₅ was used as the oxide serving as the liquid phase sintering aid in (1) above; and (ii) a TaC polycrystalline dense body (relative density 90% or more) was also placed at the outer periphery in the graphite container in (2) above. The results of evaluation of the crystal growth thickness, warpage, and basal-plane dislocation density of the resulting substrate were as shown in Table 3.

### Example 29

A SiC single crystal substrate was prepared and evaluated in the same manner as in Example 5 except that Nb₂O₅ was used as the oxide serving as the liquid phase sintering aid in (1) above. The results of evaluation of the crystal growth thickness, warpage, and basal-plane dislocation density of the resulting substrate were as shown in Table 3.

### Example 30

A SiC single crystal substrate was prepared and evaluated in the same manner as in Example 4 except that SiO₂ was used as the oxide serving as the liquid phase sintering aid in (1) above. The results of evaluation of the crystal growth thickness, warpage, and basal-plane dislocation density of the resulting substrate were as shown in Table 3.

### Example 31

A SiC single crystal substrate was prepared and evaluated in the same manner as in Example 7 except that: (i) SiO₂ was used as the oxide serving as the liquid phase sintering aid in (1) above; and (ii) a TaC polycrystalline dense body (relative density 90% or more) was also placed at the outer periphery in the graphite container in (2) above. The results of evaluation of the crystal growth thickness, warpage, and basal-plane dislocation density of the resulting substrate were as shown in Table 3.

### Example 32

A SiC single crystal substrate was prepared and evaluated in the same manner as in Example 5 except that SiO₂ was used as the oxide serving as the liquid phase sintering aid in (1) above. The results of evaluation of the crystal growth thickness, warpage, and basal-plane dislocation density of the resulting substrate were as shown in Table 3.

### Example 33 (Comparative Example)

A SiC single crystal substrate was prepared and evaluated in the same manner as in Example 1 except that in (4) above, heating was conducted at an average furnace temperature of 2,450° C. without forming a temperature gradient (that is, the temperatures at the upper and lower parts of the effective working zone were made substantially the same). The results of evaluation of the crystal growth thickness, warpage, and basal-plane dislocation density of the resulting substrate were as shown in Table 3.

### Example 34

A SiC single crystal substrate was prepared and evaluated in the same manner as in Example 1 except that a temperature gradient of 0.36° C./mm was formed such that the temperature increased from the upper part to the lower part of the firing furnace, and heating was conducted at an average furnace temperature of 2,450° C. in (4) above. The results of evaluation of the crystal growth thickness, warpage, and basal-plane dislocation density of the resulting substrate were as shown in Table 3.

### Example 35

A SiC single crystal substrate was prepared and evaluated in the same manner as in Example 1 except that the content of the oxide relative to the content of the SiC powder was set to 36.5% by weight in (1) above. The results of evaluation of the crystal growth thickness, warpage, and basal-plane dislocation density of the resulting substrate were as shown in Table 3.

### Example 36

A SiC single crystal substrate was prepared and evaluated in the same manner as in Example 1 except that a temperature gradient of 0.06° C./mm was formed such that the temperature increased from the upper part to the lower part of the firing furnace, and heating was conducted at an average furnace temperature of 2,550° C. in (4) above. The results of evaluation of the crystal growth thickness, warpage, and basal-plane dislocation density of the resulting substrate were as shown in Table 3.

### Example 37 (Comparative Example)

A SiC single crystal substrate was prepared and evaluated in the same manner as in Example 1 except that no liquid phase sintering aid was added, that is, commercially available p-SiC powder (volume-based D50 particle size: 65.0 μm) was used instead of the SiC mixed powder in (1) above. The results of evaluation of the crystal growth thickness, warpage, and basal-plane dislocation density of the resulting substrate were as shown in Table 3.

### Example 38

A SiC single crystal substrate was prepared and evaluated in the same manner as in Example 1 except that a temperature gradient of 0.28° C./mm was formed such that the temperature increased from the upper part to the lower part of the firing furnace, and heating was conducted at an average furnace temperature of 2,250° C. in (4) above. The results of evaluation of the crystal growth thickness, warpage, and basal-plane dislocation density of the resulting substrate were as shown in Table 3.

Example 39 (Comparative Example) A SiC single crystal substrate was prepared and evaluated in the same manner as in Example 1 except that a temperature gradient of 0.14° C./mm was formed such that the temperature increased from the upper part to the lower part of the firing furnace, and heating was conducted at an average furnace temperature of 2,225° C. in (4) above. The results of evaluation of the crystal growth thickness, warpage, and basal-plane dislocation density of the resulting substrate were as shown in Table 3.

### [Table 1]

TABLE 1

| | Manufacturing conditions of SiC single crystal substrate | | | | | | | | | | |
|---|---|---|---|---|---|---|---|---|---|---|---|
| | | Content | | | | | | | | | |
| | | of oxide | | | | | | | | | |
| | | relative | | | | | | | Position of dense body | | |
| | | to content | | | Temperature | | | | Top | | Outer |
| | | of SiC | | Average | gradient | | | | surface | Bottom | periphery |
| | Type | powder | | furnace | (absolute | Number of graphite | | | of | of | of |
| | of | (% by | Position of seed crystal | temperature | value) | crucibles arranged | | | powder | powder | powder |
| | oxide | mass) | placed | (° C.) | (° C./mm) | Horizontal | Vertical | Total | layer | layer | layer |
| Ex. 1 | Gd₂O₃ | 8.1 | Top surface of powder layer | 2430 | 0.11 | 2 | 2 | 4 | — | — | — |
| Ex. 2 | Gd₂O₃ | 16.2 | Top surface of powder layer | 2445 | 0.17 | 3 | 5 | 15 | — | Placed | Placed |
| Ex. 3 | Gd₂O₃ | 32.4 | Top surface of powder layer | 2490 | 0.06 | 3 | 25 | 75 | — | — | Placed |
| Ex. 4 | Gd₂O₃ | 4.1 | Top surface of powder layer | 2450 | 0.28 | 10 | 5 | 50 | — | — | — |
| Ex. 5 | Gd₂O₃ | 2.0 | Top surface of powder layer | 2508 | 0.01 | 2 | 30 | 60 | — | Placed | — |
| Ex. 6 | Gd₂O₃ | 1.0 | Top surface of powder layer | 2445 | 0.12 | 7 | 10 | 70 | — | Placed | — |
| Ex. 7 | Gd₂O₃ | 0.8 | Top surface of powder layer | 2375 | 0.14 | 1 | 2 | 2 | — | Placed | — |
| Ex. 8 | Gd₂O₃ | 24.3 | Top surface of powder layer | 2463 | 0.21 | 2 | 1 | 2 | — | Placed | Placed |
| Ex. 9 | Gd₂O₃ | 8.1 | Bottom of powder layer | 2430 | 0.11 | 2 | 2 | 4 | — | — | — |
| Ex. 10 | Gd₂O₃ | 16.2 | Bottom of powder layer | 2445 | 0.17 | 3 | 5 | 15 | Placed | — | Placed |
| Ex. 11 | Gd₂O₃ | 32.4 | Bottom of powder layer | 2490 | 0.06 | 3 | 25 | 75 | — | — | Placed |
| Ex. 12 | Gd₂O₃ | 4.1 | Bottom of powder layer | 2450 | 0.28 | 10 | 5 | 50 | — | — | — |
| Ex. 13 | Gd₂O₃ | 2.0 | Bottom of powder layer | 2508 | 0.01 | 2 | 30 | 60 | Placed | — | — |
| Ex. 14 | Gd₂O₃ | 1.0 | Bottom of powder layer | 2445 | 0.12 | 7 | 10 | 70 | Placed | — | — |
| Ex. 15 | Gd₂O₃ | 0.8 | Bottom of powder layer | 2375 | 0.14 | 1 | 2 | 2 | Placed | — | — |
| Ex. 16 | Gd₂O₃ | 24.3 | Bottom of powder layer | 2463 | 0.21 | 2 | 1 | 2 | Placed | — | Placed |
| Ex. 17 | Sm₂O₃ | 8.1 | Top surface of powder layer | 2430 | 0.11 | 2 | 2 | 4 | — | — | — |
| Ex. 18 | La₂O₃ | 8.1 | Top surface of powder layer | 2430 | 0.11 | 2 | 2 | 4 | — | — | — |
| Ex. 19 | Nd₂O₃ | 8.1 | Top surface of powder layer | 2430 | 0.11 | 2 | 2 | 4 | — | — | — |
| Ex. 20 | Y₂O₃ | 8.1 | Top surface of powder layer | 2430 | 0.11 | 2 | 2 | 4 | — | Placed | — |
| Ex. 21 | CeO₂ | 8.1 | Top surface of powder layer | 2430 | 0.11 | 2 | 2 | 4 | — | Placed | — |
| Ex. 22 | Gd₂O₃ | 8.1 | Embedded in powder layer | 2430 | 0.11 | 2 | 2 | 4 | — | — | — |
| Ex. 23 | Sm₂O₃ | 8.1 | Embedded in powder layer | 2430 | 0.11 | 2 | 2 | 4 | Placed | Placed | — |

TABLE 2

| | Manufacturing conditions of SiC single crystal substrate | | | | | | | | | | |
|---|---|---|---|---|---|---|---|---|---|---|---|
| | | Content | | | | | | | | | |
| | | of oxide | | | | | | | | | |
| | | relative | | | | | | | Position of dense body | | |
| | | to content | | | Temperature | | | | Top | | Outer |
| | | of SiC | | Average | gradient | | | | surface | Bottom | periphery |
| | Type | powder | | furnace | (absolute | Number of graphite | | | of | of | of |
| | of | (% by | Position of placement of | temperature | value) | crucibles arranged | | | powder | powder | powder |
| | oxide | mass) | seed crystal | (° C.) | (° C./mm) | Horizontal | Vertical | Total | layer | layer | layer |
| Ex. 24 | Al₂O₃ | 4.1 | Top surface of powder layer | 2450 | 0.28 | 10 | 5 | 50 | — | — | — |
| Ex. 25 | Al₂O₃ | 0.8 | Top surface of powder layer | 2375 | 0.14 | 1 | 2 | 2 | — | Placed | Placed |
| Ex. 26 | Al₂O₃ | 2.0 | Top surface of powder layer | 2508 | 0.01 | 2 | 30 | 60 | — | Placed | — |
| Ex. 27 | Nb₂O₅ | 4.1 | Top surface of powder layer | 2450 | 0.28 | 10 | 5 | 50 | — | — | — |
| Ex. 28 | Nb₂O₅ | 0.8 | Top surface of powder layer | 2375 | 0.14 | 1 | 2 | 2 | — | Placed | Placed |
| Ex. 29 | Nb₂O₅ | 2.0 | Top surface of powder layer | 2508 | 0.01 | 2 | 30 | 60 | — | Placed | — |
| Ex. 30 | SiO₂ | 4.1 | Top surface of powder layer | 2450 | 0.28 | 10 | 5 | 50 | — | — | — |
| Ex. 31 | SiO₂ | 0.8 | Top surface of powder layer | 2375 | 0.14 | 1 | 2 | 2 | — | Placed | Placed |
| Ex. 32 | SiO₂ | 2.0 | Top surface of powder layer | 2508 | 0.01 | 2 | 30 | 60 | — | Placed | — |
| Ex. 33* | Gd₂O₃ | 8.1 | Top surface of powder layer | 2450 | 0 | 2 | 2 | 4 | — | — | — |
| Ex. 34 | Gd₂O₃ | 8.1 | Top surface of powder layer | 2450 | 0.36 | 2 | 2 | 4 | — | — | — |
| Ex. 35 | Gd₂O₃ | 36.5 | Top surface of powder layer | 2430 | 0.11 | 2 | 2 | 4 | — | — | — |
| Ex. 36 | Gd₂O₃ | 8.1 | Top surface of powder layer | 2550 | 0.06 | 2 | 2 | 4 | — | — | — |
| Ex. 37* | — | 0 | Top surface of powder layer | 2430 | 0.11 | 2 | 2 | 4 | — | — | — |
| Ex. 38 | Gd₂O₃ | 8.1 | Top surface of powder layer | 2250 | 0.28 | 2 | 2 | 4 | — | — | — |
| Ex. 39* | Gd₂O₃ | 8.1 | Top surface of powder layer | 2225 | 0.14 | 2 | 2 | 4 | — | — | — |

*indicates Comparative Example

TABLE 3

Evaluation of SiC single crystal substrate

| | Crystal | | Basal-plane |
|---|---|---|---|
| | growth | | dislocation |
| | thickness | Warpage | density |
| Ex. 1 | A | A | A |
| Ex. 2 | A | A | A |
| Ex. 3 | A | A | A |
| Ex. 4 | A | A | A |
| Ex. 5 | A | A | A |
| Ex. 6 | A | A | A |
| Ex. 7 | A | A | A |
| Ex. 8 | A | A | A |
| Ex. 9 | A | A | A |
| Ex. 10 | A | A | A |
| Ex. 11 | A | A | A |
| Ex. 12 | A | A | A |
| Ex. 13 | A | A | A |
| Ex. 14 | A | A | A |
| Ex. 15 | A | A | A |
| Ex. 16 | A | A | A |
| Ex. 17 | A | A | A |
| Ex. 18 | A | A | A |
| Ex. 19 | A | A | A |
| Ex. 20 | A | A | A |
| Ex. 21 | A | A | A |
| Ex. 22 | A | A | A |
| Ex. 23 | A | A | A |
| Ex. 24 | B | A | B |
| Ex. 25 | B | A | B |
| Ex. 26 | B | A | B |
| Ex. 27 | B | A | B |
| Ex. 28 | B | A | B |
| Ex. 29 | B | A | B |
| Ex. 30 | B | A | B |
| Ex. 31 | B | A | B |
| Ex. 32 | B | A | B |
| Ex. 33* | C | A | A |
| Ex. 34 | A | B | B |
| Ex. 35 | A | B | B |
| Ex. 36 | A | B | A |
| Ex. 37* | C | A | A |
| Ex. 38 | B | A | B |
| Ex. 39* | C | A | B |

*indicates Comparative Example

Based on the results of Examples 1 to 32, 34 to 36, and 38, it was found that, although the reason is unknown, when a SiC single crystal serving as the seed crystal and a SiC mixed powder layer containing a liquid phase sintering aid are brought into contact with each other and heat-treated in a firing furnace having a predetermined temperature gradient (preferably in the effective working zone), multiple SiC single crystal substrates with small warpage, low basal-plane dislocation density, and large crystal growth thickness can be simultaneously manufactured. On the other hand, based on the results of Examples 33, 37, and 39 (Comparative Examples), it was found that high-quality SiC single crystal substrates cannot be obtained when a temperature gradient is not formed, the liquid phase sintering aid is not added, or the average furnace temperature is not sufficiently controlled.

### REFERENCE SIGNS LIST

2 Container
2a Container body
2b Container lid
4 Seed crystal
6 SiC mixed powder layer
8 Dense body
10 Firing furnace
12 Upper heater
14 Lower heater
16 Support base
18 Gas pipe
20 SiC single crystal substrate
30 SiC single crystal
G Gas

What is claimed is:

1. A method for simultaneously manufacturing multiple SiC single crystal substrates, the method comprising:
preparing a plurality of containers;
placing, in each of the plurality of containers, an SiC single crystal serving as a seed crystal and an SiC mixed powder comprising SiC powder and a liquid phase sintering aid so as to form an SiC mixed powder layer in which the SiC mixed powder is in contact with at least one surface of the SiC single crystal, wherein the liquid phase sintering aid comprises an oxide;
arranging the plurality of containers in a firing furnace so as to be aligned horizontally and/or vertically; and
heating the inside of the firing furnace to form a temperature gradient in which the temperature increases or decreases from an upper part to a lower part of the firing furnace, and subjecting the plurality of containers containing the seed crystal and the SiC mixed powder to heat treatment at an average furnace temperature of 2,240 to 2,560° C., whereby an SiC single crystal is grown on the seed crystal.

2. The method according to claim 1, wherein the oxide comprises a rare earth element.

3. The method according to claim 1, wherein the content of the oxide is 0.5 to 33.0% by weight relative to the content of the SiC powder.

4. The method according to claim 1, wherein the average furnace temperature during the heat treatment is 2,370 to 2,515° C.

5. The method according to claim 1, wherein the temperature gradient is 0.01 to 0.40° C./mm.

6. The method according to claim 1, wherein the heat treatment is performed while providing a temperature gradient such that the temperature on the side of the container closer to the seed crystal is lower than that on the side of the container closer to the SiC mixed powder layer.

7. The method according to claim 1, wherein the number of the containers is 2 to 80.

8. The method according to claim 2, wherein the rare earth element comprises at least one selected from the group consisting of Gd, Sm, La, Nd, Y, and Ce.

9. The method according to claim 1, wherein a dense body having a relative density of 90% or more is placed on the bottom surface and/or the top surface of the SiC mixed powder layer, excluding the surface in contact with the seed crystal.

10. The method according to claim 1, wherein a dense body having a relative density of 90% or more is placed on the outer periphery of the SiC mixed powder layer.

11. The method according to claim 1, wherein a dense body having a relative density of 90% or more is placed on the bottom surface and/or the top surface of the SiC mixed powder layer, excluding the surface in contact with the seed crystal, and a dense body having a relative density of 90% or more is also placed on the outer periphery of the SiC mixed powder layer.

12. The method according to claim 1, wherein the firing furnace comprises an upper heater at the upper part of the firing furnace and a lower heater at the lower part of the firing furnace, and during the heat treatment, the upper heater and the lower heater are set to different temperatures so as to provide the temperature gradient and the average furnace temperature.
